(19) United States
(12) Patent Application Publication
(10) Pub. No.: US 2007/0259469 A1
(43) Pub. Date: Nov. 8, 2007

(54) Liquid detection method and apparatus

(75) Inventor: Frank Bernard Santagato, Jacksonville, FL (US)

Correspondence Address: RAJ ABHYANKER, LLP;c/o PORTFOLIOIP, P.O. BOX 52050, MINNEAPOLIS, MN, 55402, US

(73) Assignee: Stopflow Technologies, Inc.

(21) Appl. No.: 11/429,833

(22) Filed: May 8, 2006

(51) Int. Cl. H01L 21/00; H01L 21/8242

(52) U.S. Cl. 438/49; 438/253; 438/108

(57) ABSTRACT

A liquid detection method, apparatus, and system are disclosed. In one embodiment, an apparatus includes a non-conductive housing base having an absorbing material to expand on contact with a liquid and a conductive material coupled with the absorbing material to form a closed circuit when the conductive material contacts a conductive surface above the apparatus. The absorbing material may be a sponge material and/or any other material (e.g., a resin, a polymer, a porous material, etc.) having an expansion coefficient sufficient to cause the conductive material to rise when the sponge makes contact with the liquid. The apparatus may be a removable cartridge of a liquid sensing device.

### FIELD OF TECHNOLOGY

This disclosure relates generally to technical fields of detection devices and, in one embodiment, to a method, apparatus, and/or system of liquid detection.

### BACKGROUND

A structure (e.g., a home, an office, a building, etc.) may have a system to transport a liquid (e.g., water, waste, etc.) throughout the structure (e.g., water pipes, gas pipes, appliances, such as an ice maker, a dishwasher, a drinking water filtration equipment, etc.). The structure may house a person (e.g., having allergies to mold caused by the presence of the liquid) and/or an article sensitive to the presence of the liquid (e.g., a carpet, a wood beam, a computer, a data storage device, a power system, a document, furniture, etc.). The structure may also be constructed to shelter the person and/or the article from natural precipitation (e.g., snow, rain, etc.) and/or a severe weather condition (e.g., a hurricane, a flood, etc.).

The liquid may escape (e.g., leak, seep, drip, etc.) into the structure and damage the structure and/or the article. An extended delay in detecting the liquid may cause mold, allergens, fungus, and/or rot to deteriorate the structure and/or the article. Additionally, the liquid may cause a stain on a wall of the structure (e.g., a water spot), which may be unsightly to the person housed in the structure. In addition, the liquid may cause a safety hazard in the structure (e.g., insects may breed, the person may slip and fall, vegetation may grow, etc.) In addition, damage caused by the liquid (e.g., when leaking) may cause excessive financial costs to an owner, to an insurance carrier and/or to others financially responsible for the structure.

A liquid detection system may have a pair of electrodes (e.g., electrical probes) to detect a conductive liquid (e.g., an unpurified liquid that may include particulates which conduct electricity) when a circuit is formed between the pair of electrodes through the conductive liquid. The liquid detection system may include a series of complicated impendence resisters that require a constant source of electrical power (e.g., DC voltage) to operate. In addition, the liquid detection system may require an expensive back-up battery to ensure operation when a primary source of electrical power malfunctions. These issues can make the liquid detection system expensive, cumbersome, and inefficient.

### SUMMARY

A liquid detection method, apparatus, and system are disclosed. In one aspect, an apparatus includes a non-conductive housing base having an absorbing material to expand on contact with a liquid and a conductive material coupled with the absorbing material to form a closed circuit when the conductive material contacts a conductive surface above the apparatus. The absorbing material may be a sponge material (e.g., a compressed sponge) and/or any other material (e.g., a resin, a polymer, a porous material, etc.) having an expansion coefficient sufficient to cause the conductive material to rise when the sponge makes contact with the liquid. The conductive material coupled to the absorbing material may be a removable cartridge of a liquid sensing device. The removable cartridge may be inserted through a variety of methods; clip in, slide in, snap in, slide in, screw in, bolt in, etc.

In addition, first conductive extension and a second conductive extension may be formed on a surround base of the housing base and adjoined with the conductive material such that an electric charge is capable of flowing between the first conductive extension and the second conductive extension. An alert module may generate a notification data when the conductive material contacts the conductive surface. The alert module may wirelessly communicate the notification data to a location external to a controlled environment when the conductive material contacts the conductive surface.

A gap may be formed between the apparatus and a packaging structure encompassing the apparatus, such that the gap is between the conductive material and the conductive surface, and wherein the conductive surface may be on a cover of the packaging structure.

In another aspect, a method for manufacturing a water sensor includes forming a conductive surface on a removable cover of a housing base, coupling a conductive material to an absorbing material, and attaching the absorbing material having the conductive material to a recess of the housing base below the removable cover, such that a gap is formed between the removable cover and the absorbing material. The method may include applying an alert module to the housing base to communicate a notification when the absorbing material expands in a presence of a liquid. The conductive material may contact the conductive surface and form a closed circuit when the absorbing material expands. Forming of a pair of conductive extensions may couple to the conductive material such that the pair of extensions extend from the conductive material. In addition, a cavity over a surround base may be formed that encompasses the absorbing material having the conductive material. The pair of conductive extensions may form an open circuit when detached from the surround base upon the absorbing material expanding in a presence of a liquid. The surround base may be interchangeably coupled in a location of the recess of the housing base.

In yet another aspect, a system includes a control module, a plurality of sensors configured to automatically communicate with the control module, each of the plurality of sensors may include an absorbing material capable of expansion on contact with a liquid, and a conductive material adjacent to the absorbing material to form an open circuit and/or a closed circuit when the absorbing material expands. The sensors may include an alert module that may wirelessly communicate with the control module when the absorbing material expands beyond a threshold value. The control module may be shared across any number of sensors and other devices in a structure. The control module may automatically choke a liquid source location when the absorbing material expands. At least some of the sensors may each be physically less than two inches by two inches in a length, in a width, and in a height, such that the at least some of the sensors can be integrated inside a structural wall. A data processing system may be coupled to the control module through a network to remotely detect a presence of a liquid in an enclosed structure when the absorbing material expands. The control module may automatically communicate through a network to a location external to the enclosed structure when the absorbing material in at least one of the sensors expands.

The method may be executed in a form of a machine-readable medium embodying a set of instructions that, when executed by a machine, cause the machine to perform any of the operations disclosed herein. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 is a side view of a cartridge having an absorbing material, according to one embodiment.

FIG. 2 is a perspective view of a liquid sensor having a first conductive surface and a second conductive surface and the cartridge of FIG. 1, according to one embodiment.

FIGS. 3A-3B are cross-sectional views of the liquid sensor of FIG. 2 having the cartridge of FIG. 1, according to one embodiment.

FIGS. 4A-4B are cross-sectional views of a liquid sensor having an alarm module, according to another embodiment.

FIGS. 5A-5B are cross sectional views of a system for detecting a liquid having a control panel, according to one embodiment.

FIG. 6 is a side view of a cartridge having a first conductive extension and a second conductive extension, according to one embodiment.

FIG. 7 is a perspective view of a liquid sensor including the cartridge of FIG. 6, according to one embodiment.

FIGS. 8A-8B are cross-sectional views of the liquid sensor of FIG. 7, according to one embodiment.

FIG. 9 is a process flow of manufacturing a liquid sensor, according to one embodiment.

Other features of the present embodiments will be apparent from the accompanying drawings and from the detailed description that follows.

### DETAILED DESCRIPTION

A liquid detection method, apparatus, and system are disclosed. In the following description, for purposes of explanation, numerous specific details are set forth in order to provide a thorough understanding of the various embodiments. It will be evident, however, to one skilled in the art that the various embodiments may be practiced without these specific details. In addition, it will be appreciated that the various embodiments discussed herein may/may not be the same embodiment, and may be grouped into various other embodiments not explicitly disclosed herein.

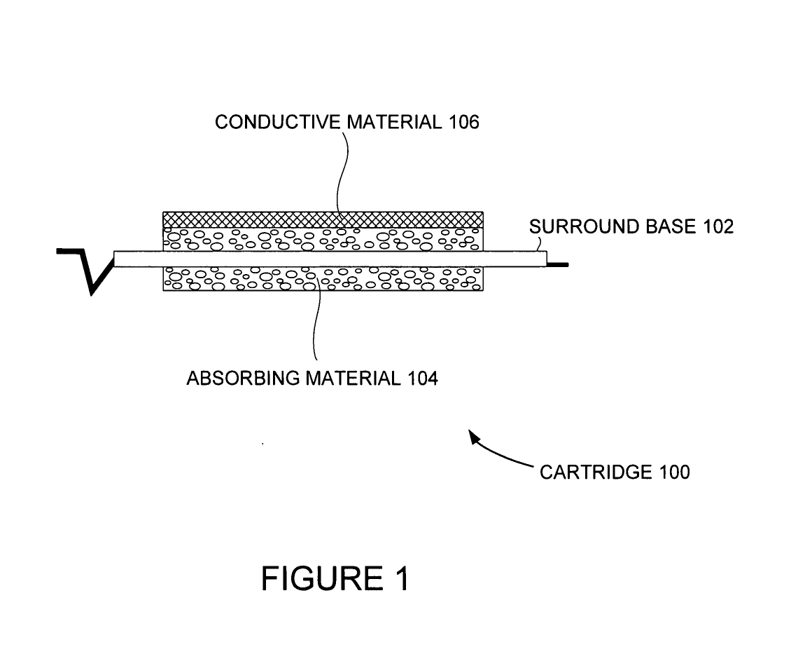

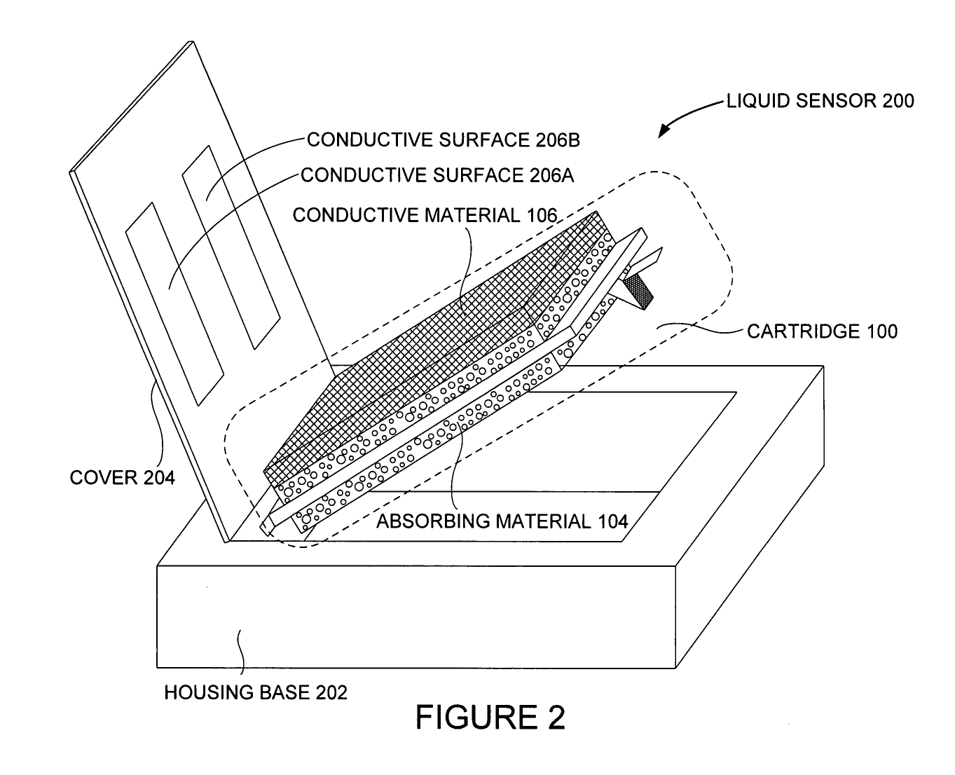

In one embodiment, an apparatus (e.g, a water sensor 200 of FIG. 2, etc.) includes a non-conductive housing base (e.g., a housing base 202 of FIG. 2) having an absorbing material (e.g., an absorbing material 104 of FIG. 1) to expand on contact with a liquid (e.g., water) and a conductive material (e.g., a conductive material 106 of FIG. 1) coupled with the absorbing material to form a closed circuit when the conductive material contacts a conductive surface (e.g., a first conductive surface 206A and a second conductive surface 206B of FIG. 2) above the apparatus.

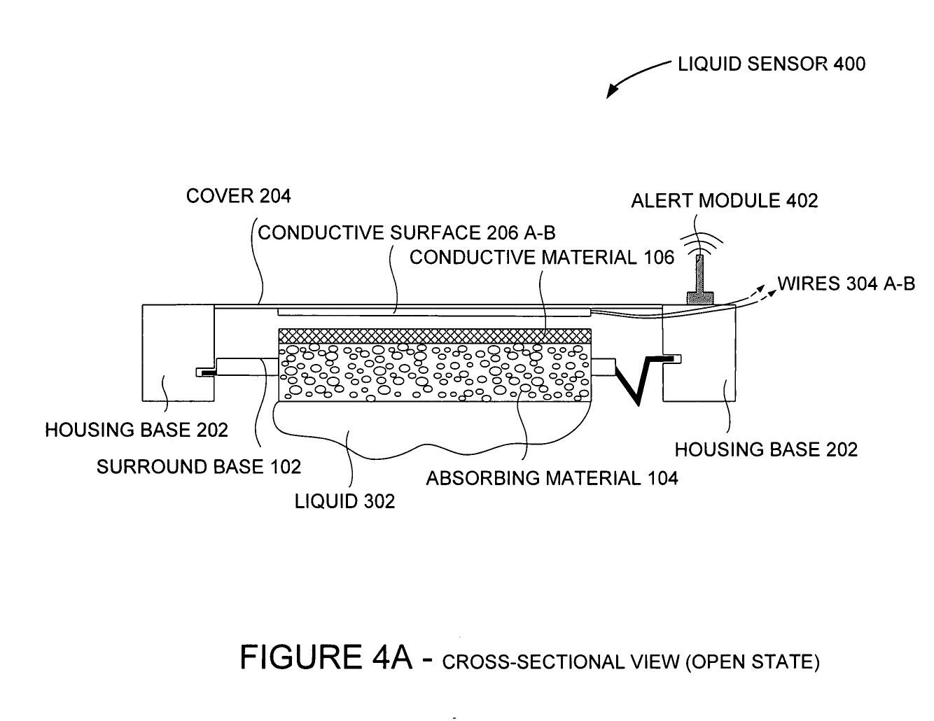

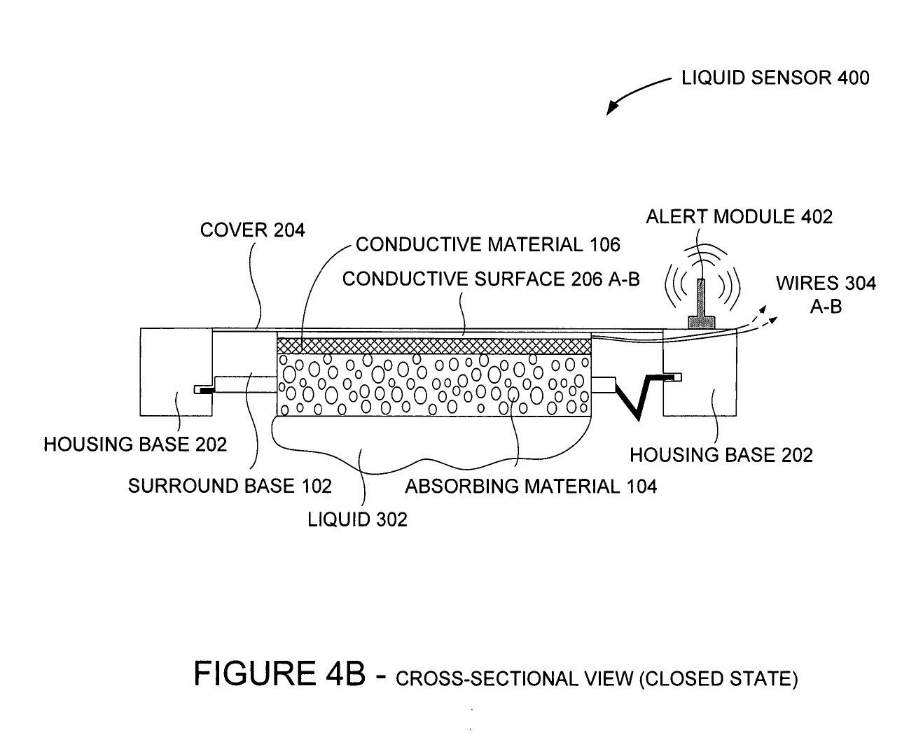

In another embodiment, a method for manufacturing a liquid sensor includes forming a conductive surface (e.g., the first conductive surface 206A and the second conductive surface 206B of FIG. 2) on a removable cover (e.g., a cover of FIG. 2) of a housing base (e.g., the housing base 202 of FIG. 2), coupling a conductive material (e.g., the conductive material 106 of FIG. 1) to an absorbing material (e.g., the absorbing material 104 of FIG. 1), and attaching the absorbing material having the conductive material to a recess of the housing base below the removable cover, such that a gap is formed between the removable cover and the absorbing material. The method may include applying an alert module (e.g., an alert module 402 of FIG. 4) to the housing base to communicate a notification when the absorbing material expands in a presence of a liquid (e.g., water). The conductive material may contact the conductive surface forming a closed circuit when the absorbing material expands.

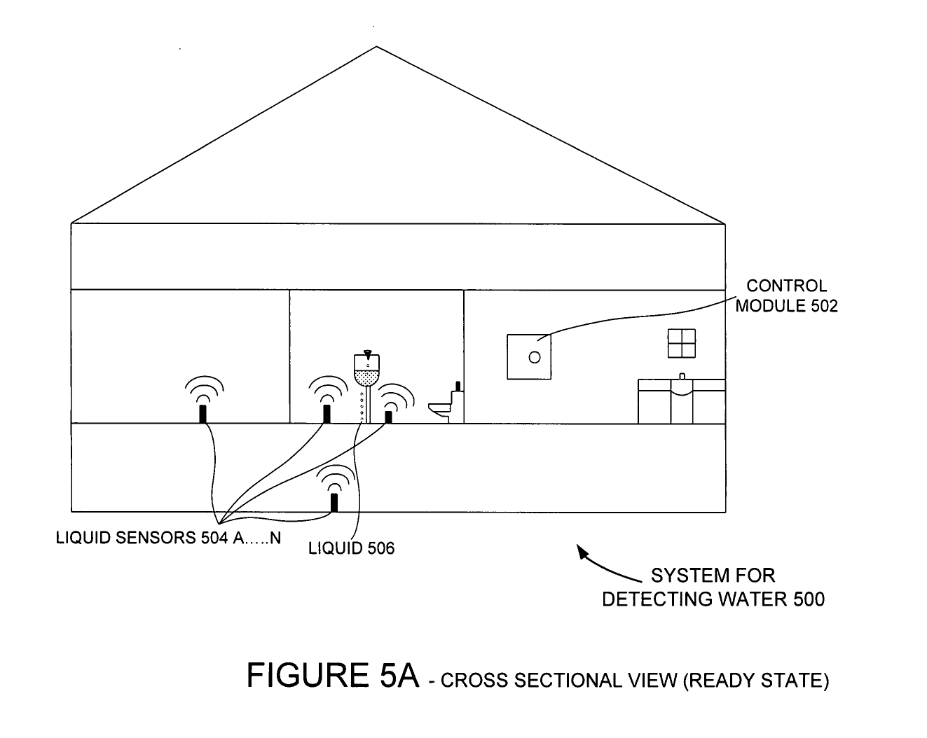

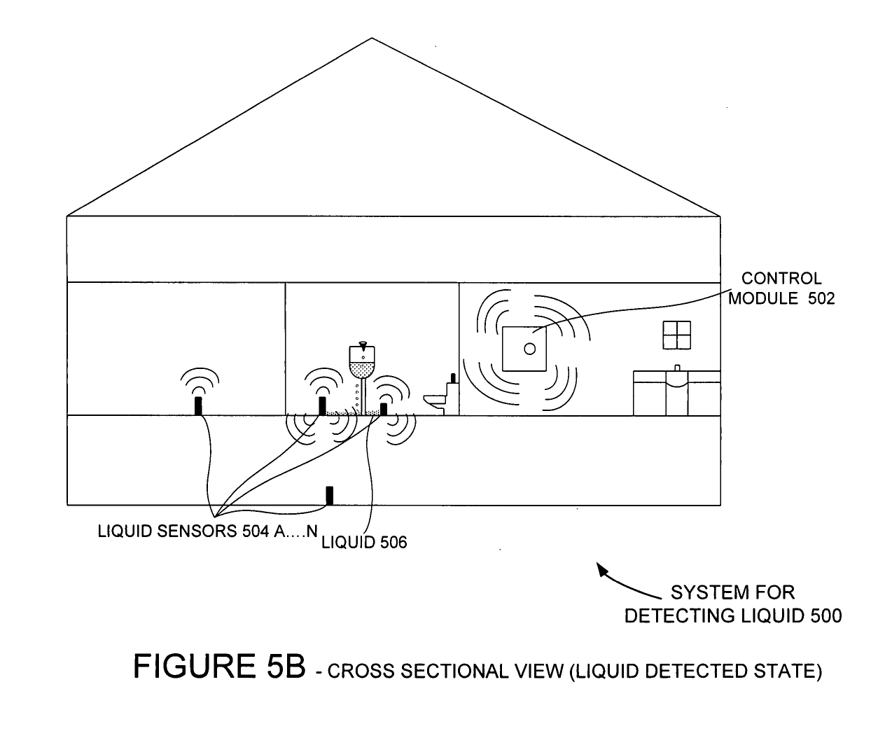

In yet another embodiment, a system includes a control module (e.g., a control module 502 of FIG. 5), a plurality of sensors (e.g., liquid sensors 504A-N of FIG. 5) configured to automatically communicate with the control module, each of the plurality of sensors to include an absorbing material (e.g., the absorbing material 104 of FIG. 1) capable of expansion on contact with a liquid, and a conductive material adjacent to the absorbing material to form at least one of an open circuit and a closed circuit when the absorbing material expands. At least one of the sensors includes an alert module (e.g., the alert module 402 of FIG. 4) that may wirelessly communicate with the control module when the absorbing material expands beyond a threshold value.

FIG. 1 is a side view of a cartridge 100 (e.g., a removable cartridge) having an absorbing material 104 (e.g., a sponge), according to one embodiment. The cartridge 100 further includes a surround base 102 (e.g., a non-conductive plastic surround material) and a conductive material 106 coupled to the absorbing material. In one embodiment, the cartridge 100 of FIG. 1 may be inserted and/or removed after insertion into a liquid sensor of FIG. 2.

FIG. 2 is a perspective view of a liquid sensor 200 having a first conductive surface 206A (e.g., a metal strip) and a second conductive surface 206B and the cartridge 100 (e.g., a removable cartridge) of FIG. 1, according to one embodiment. The first conductive surface 206A and the second conductive surface 206B may be formed on a cover 204 to a housing base 202. While FIG. 2 illustrates two conductive surfaces (e.g., the first conductive surface 206A and the second conductive surface 206B), in alternate embodiments, it should be noted that there may be an number of conductive surfaces formed on the cover 204.

It should be noted that in an alternate embodiment, the cartridge 100 is not enclosed in a separate housing such as the housing base 202. For example, the cartridge 100 may stand alone (e.g., one piece) to form a liquid sensor (e.g., similar to the liquid sensor 200 of FIG. 2 without the housing base 202). As such, the cartridge 100 may be “constructed” with the absorbing material 104 inside, in the alternate embodiment. In the event that the absorbing material 104 gets wet, the whole liquid sensor may need to be replaced, not just the absorbing material 104 in the alternate embodiment.

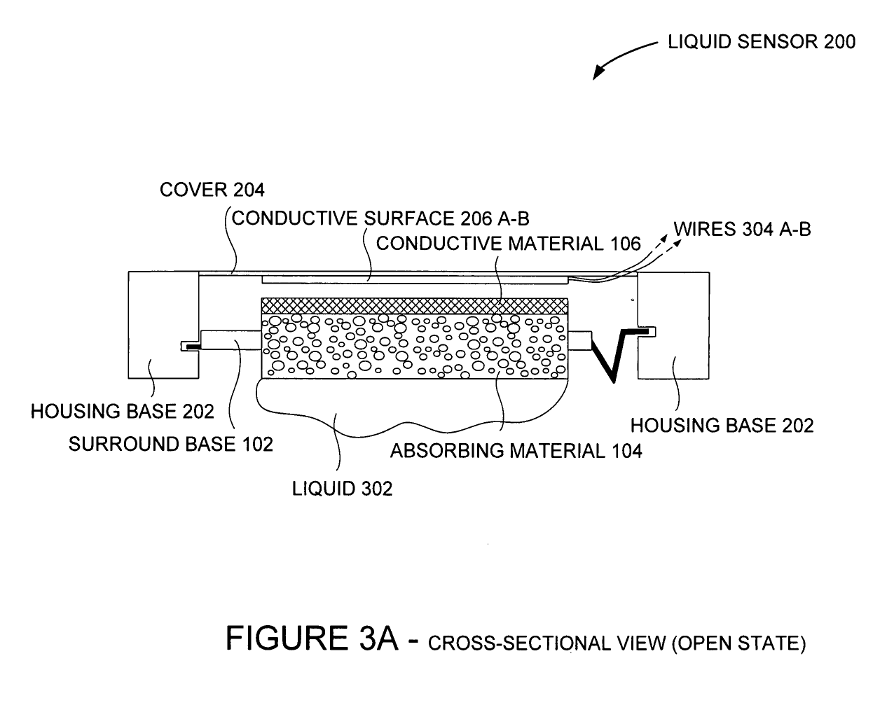

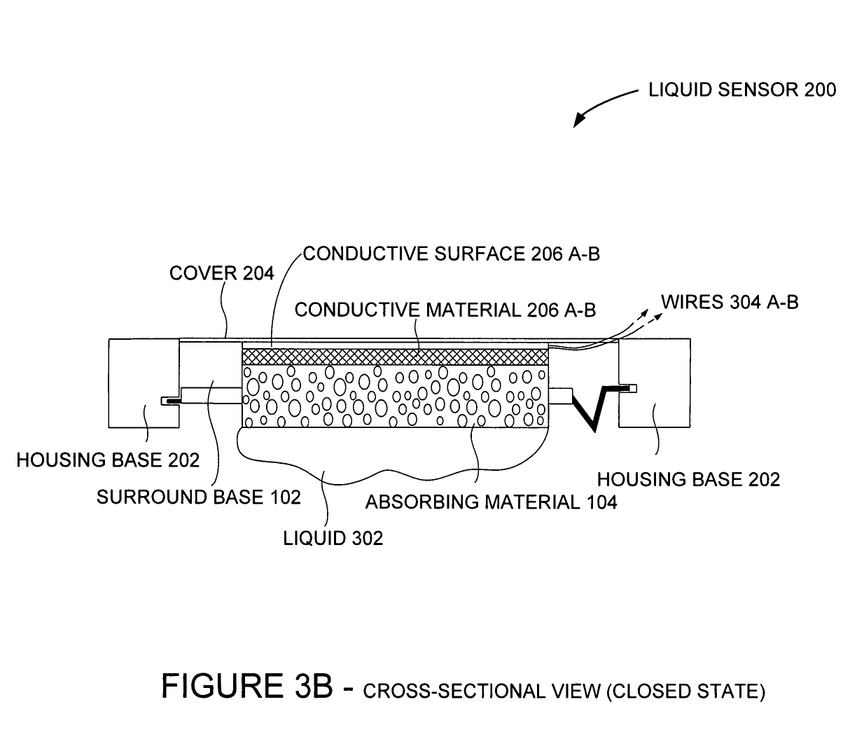

FIGS. 3A-3B are cross-sectional views of the liquid sensor 200 (e.g., water sensor) of FIG. 2 having the cartridge 100 (e.g., a removable cartridge) of FIG. 1, according to one embodiment. FIG. 3A illustrates the open state of the liquid sensor 200. A gap (e.g., a cavity) that may be formed between the cartridge 100 and the first conductive surface 206A and the second conductive surface 206B of the cover 204 (e.g., an open circuit). The gap may prevent a flow of an electric charge from the first conductive surface 206A to the second conductive surface 206B. When a liquid 302 (e.g., water) is present, the absorbing material 104 (e.g., a sponge) may absorb the liquid 302, which may cause the conductive material 106 to rise until contact is made with the first conductive surface 206A and the second conductive surface 206B, as illustrated in FIG. 3B.

FIG. 3B illustrates the closed state of the liquid sensor 200. When contact is made between the first conductive surface 206A, the second conductive surface 206B, and the conductive material 106, an electric charge may flow from a first wire 304A (e.g., a copper wire) coupled to the first conductive surface 206A to the second conductive surface 206B via the conductive material 106 and out through a second wire 304B (e.g., a closed circuit).

FIGS. 4A-4B are cross-sectional views of a liquid sensor 400 (e.g., water sensor) having an alert module 402 (e.g., an alarm, a transmitter), according to one embodiment. FIG. 4A illustrates the open state for the liquid sensor 400. A gap (e.g., a cavity) that may be formed between the cartridge 100 and the first conductive surface 206A and the second conductive surface 206B of the cover 204 (e.g., an open circuit). The gap may prevent a flow of an electric charge from the first conductive surface 206A to the second conductive surface 206B. When a liquid 302 (e.g., water) is present, the absorbing material 104 (e.g., a sponge) may absorb the liquid 302, which may cause the conductive material 106 to rise until contact is made with the first conductive surface 206A and the second conductive surface 206B, as illustrated in FIG. 4B.

FIG. 4B illustrates the closed state of the liquid sensor 400. When contact is made between the first conductive surface 206A, the second conductive surface 206B, and the conductive material 106, an electric charge may flow from a first wire 304A (e.g., a copper wire) coupled to the first conductive surface 206A to the second conductive surface 206B via the conductive material 106 and out through a second wire 304B (e.g., a closed circuit). The alert module 402 may generate a notification data (e.g., an alarm, a message, etc.). In one embodiment, the alarm module 402 may communicate the notification data to a location external to a controlled environment (e.g., a data processing system, a home security network, etc.).

FIGS. 5A-5B are cross sectional views of a system for detecting a liquid 500 having a control module 502 (e.g., a control panel, an automation panel, etc.), according to one embodiment. FIG. 5A illustrates the ready state of the system for detecting the liquid 500. The control module 502 may automatically communicate with a plurality of liquid sensors 504A-N (e.g., communicate wirelessly through an alert module coupled to the at least one of the liquid sensors 504A-N, communicate through a series of wires coupled to the at least one of the liquid sensors 504A-N). At least one of the plurality of liquid sensors may communicate with the control module 502 on contact with a liquid 506 as illustrated in FIG. 5B.

FIG. 5B illustrates the liquid detected state of the system for detecting the liquid 500. When the absorbing material of the at least one of the plurality of liquid sensors 504A-N expands beyond a threshold value, the at least one of the liquid sensors 504A-N may communicate with the control module 502 (e.g., via the alert module 402, via the series of wires, etc.). In one embodiment, the control module 502 may communicate (e.g., through a network, etc.) with a location external to an enclosed structure (e.g., alert a data processing system, notify a computer, sound an audible alarm, choke an external liquid source) and/or a location internal to the enclosure structure (e.g., choke a internal liquid source, communicate with other devices in the structure, etc.).

In one embodiment, at least some of the plurality of liquid sensors may be integrated inside a structural wall (e.g., liquid sensors physically less than two inches by two inches in a length, in a width, and in a height).

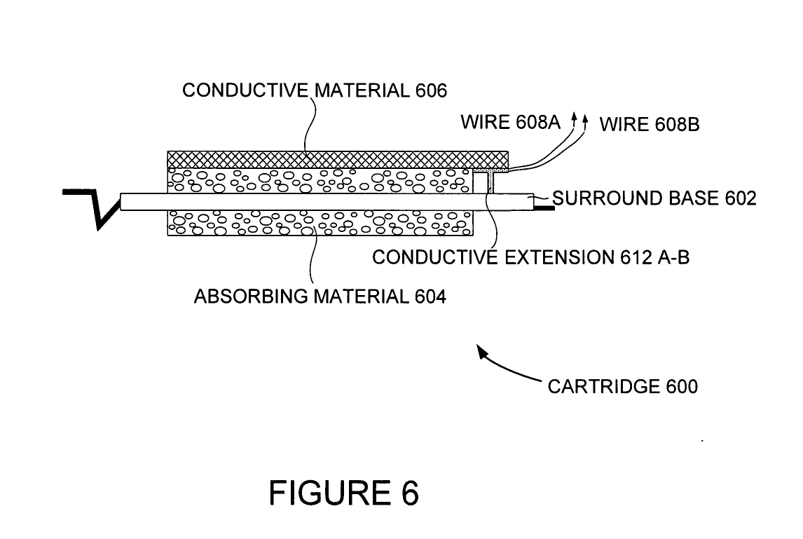

FIG. 6 is a side view of a cartridge 600 (e.g., a removable cartridge) having a first conductive extension 612A (e.g., an electric terminal) and a second conductive extension 612B, according to one embodiment. The cartridge 600 (e.g., a removable cartridge) further includes a surround base 602 (e.g., a non-conductive material) having an absorbing material 604 (e.g., a sponge), and a conductive material 606 coupled to the absorbing material 604. The conductive material 606 may also be adjoined to the first conductive extension 612A and the second conductive extension 612B. An electric charge may flow from a first wire 608A coupled to the first conductive extension 612A to the second conductive extension 612B via the conductive material 606 and out through a second wire 608B (e.g., a closed circuit).

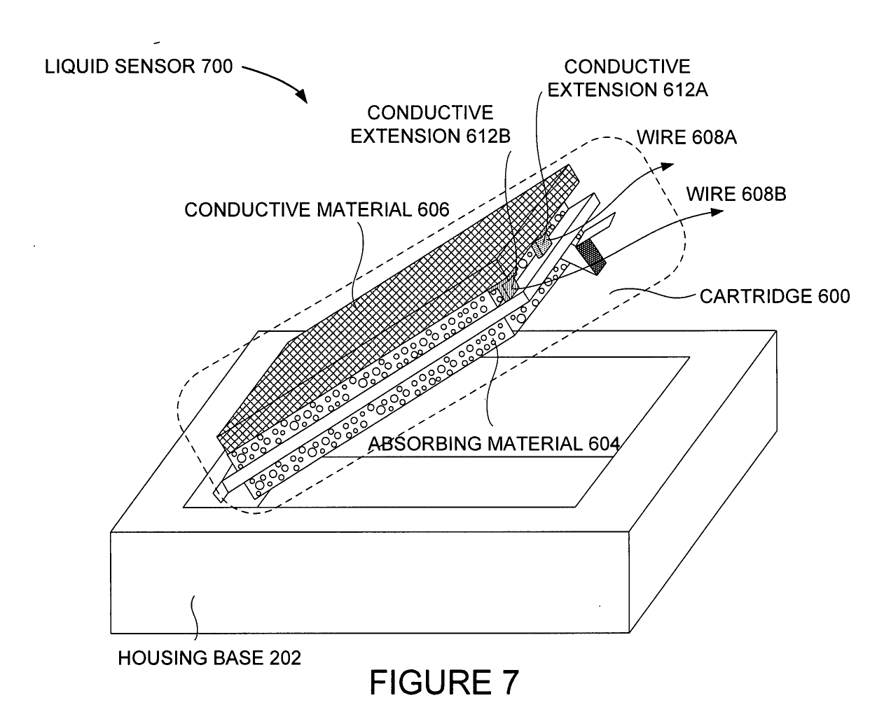

FIG. 7 is a perspective view of a liquid sensor 700 (e.g., water sensor) including the cartridge 600 (e.g., removable cartridge) of FIG. 6, according to one embodiment. For example, the housing base 202 may enclose the cartridge 600. In another embodiment, the alert module 402 may be formed on the housing base 202 to communicate with a location external to the liquid sensor (e.g., a control module, etc.).

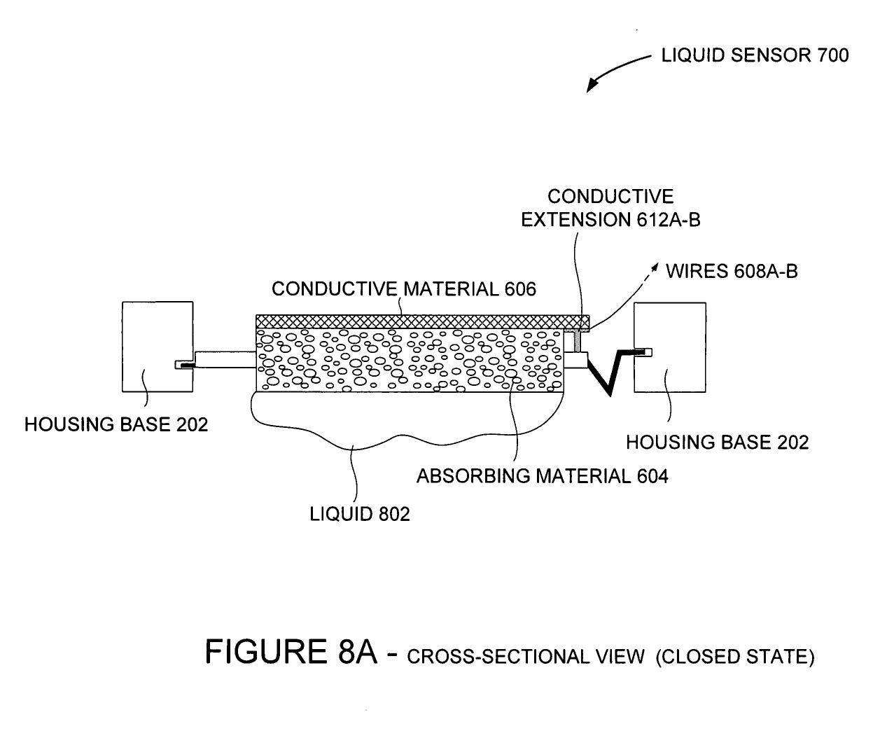

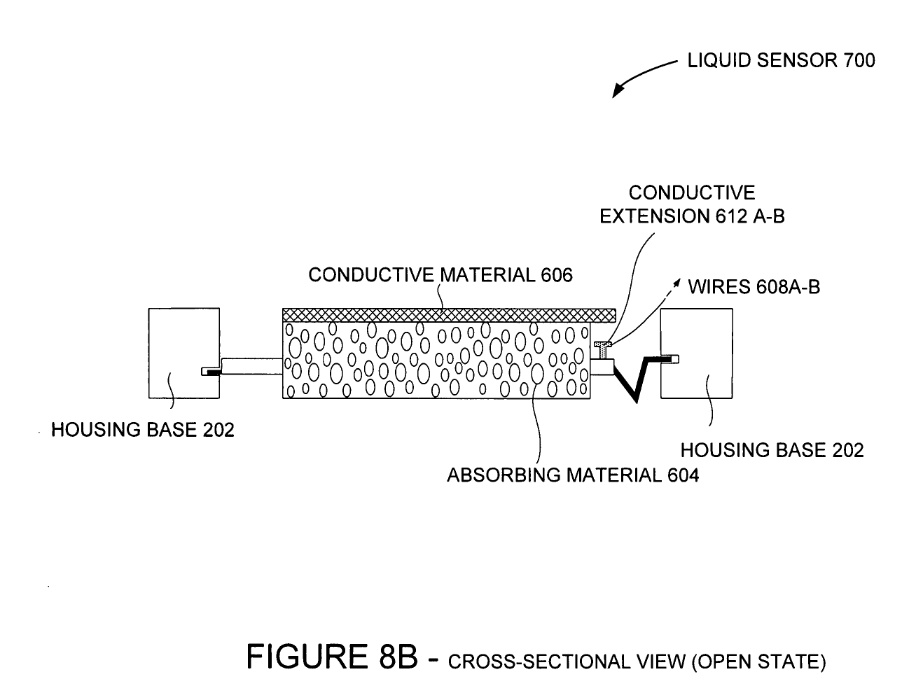

FIGS. 8A-8B are cross-sectional views of the liquid sensor 700 (e.g., water sensor), according to one embodiment. FIG. 8A illustrates the closed state of the liquid sensor 700. The first conductive extension 612A and the second conductive extension 612B may be adjoined to the conductive material 606. An electric charge may flow from the first wire 608A coupled to the first conductive extension 612A to the second conductive extension 612B and out through the second wire 608B via the conductive material 606 (e.g., a closed circuit).

FIG. 8B illustrates the open state of the liquid sensor 700. The absorbing material 604 may expand on contact with a liquid 802 and may cause the conductive material 606 to rise beyond a threshold value (e.g., opening the circuit by breaking contact with the first conductive extension 612A and the second conductive extension 612B).

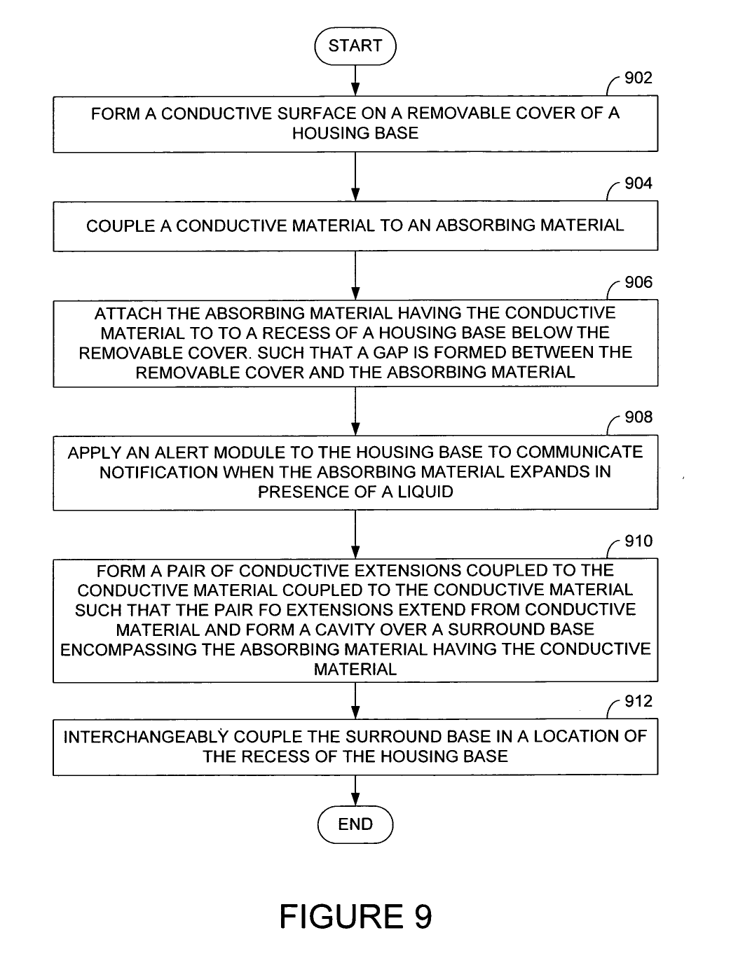

FIG. 9 is a process flow of manufacturing a liquid sensor (e.g., the liquid sensor 200 of FIG. 2, according to one embodiment. In operation 902, a conductive surface (e.g., such as the conductive surfaces 206 of FIG. 2) may be formed on a removable cover (e.g., the cover 204 of FIG. 2) of a housing base. In operation 904, a conductive material (e.g., a conductive material 106 of FIG. 1 and FIG. 2) may be coupled to an absorbing material (e.g., the absorbing material 104 of FIG. 1 and FIG. 2). In operation 906, the absorbing material having the conductive material may be attached to a recess of the housing base below the removable cover, such that a gap is formed between the removable cover and the absorbing material (e.g., as illustrated in FIG. 3). In operation 908, an alert module (e.g., an alert module 402 as illustrated in FIG. 4) may be applied to the housing base to communicate a notification when the absorbing material expands in a presence of a liquid (e.g., the liquid 302 of FIG. 3B). In operation 910, a pair of conductive extensions may be formed (e.g., as described in FIG. 6) that are coupled to the conductive material such that the pair of extensions extend from the conductive material and form a cavity over a surround base encompassing the absorbing material having the conductive material. In operation 912, the surround base may be interchangeably coupled in a location of the recess of the housing base (e.g., the housing base 202 of FIG. 2 and FIG. 7).

Although the present embodiments have been described with reference to specific example embodiments, it will be evident that various modifications and changes may be made to these embodiments without departing from the broader spirit and scope of the various embodiments. For example, the signaling layer of the alert module 402 of FIG. 4A-B and/or the control module 502 of FIG. 5A-B described herein may be enabled and operated using hardware circuitry (e.g., CMOS based logic circuitry), firmware, software and/or any combination of hardware, firmware, and/or software (e.g., embodied in a machine readable medium).

For example, the alert module 402 and/or control module 502 may be enabled using software and/or using transistors, logic gates, and electrical circuits (e.g., application specific integrated ASIC circuitry) such as an alert circuit and/or a control circuit. In addition, it will be appreciated that the various operations, processes, and methods disclosed herein may be embodied in a machine-readable medium and/or a machine accessible medium compatible with a data processing system (e.g., a computer system), and may be performed in any order (e.g., including using means for achieving the various operations). Accordingly, the specification and drawings are to be regarded in an illustrative rather than a restrictive sense.

What is claimed is:

1. An apparatus comprising:
a non-conductive housing base having an absorbing material to expand on contact with a liquid; and
a conductive material coupled with the absorbing material to form a closed circuit when the conductive material contacts a conductive surface above the apparatus.

2. The apparatus of claim 1, wherein the absorbing material is a sponge material having an expansion coefficient sufficient to cause the conductive material to rise when the sponge makes contact with the liquid.

3. The apparatus of claim 1, further comprising a first conductive extension and a second conductive extension formed on a surround base of the housing base and adjoined with the conductive material such that an electric charge is capable of flowing between the first conductive extension and the second conductive extension.

4. The apparatus of claim 1, further comprising an alert module to generate a notification data when the conductive material contacts the conductive surface.

5. The apparatus of claim 4, wherein the alert module to wirelessly communicate the notification data to a location external to a controlled environment when the conductive material contacts the conductive surface.

6. The apparatus of claim 1, wherein the conductive material coupled to the absorbing material is a removable cartridge of a liquid sensing device.

7. The apparatus of claim 6, wherein a gap is formed between the apparatus and a packaging structure encompassing the apparatus, such that the gap is between the conductive material and the conductive surface, and wherein the conductive surface on a cover of the packaging structure.

8. A method of manufacturing a liquid sensor comprising:
forming a conductive surface on a removable cover of a housing base;
coupling a conductive material to an absorbing material; and
attaching the absorbing material having the conductive material to a recess of the housing base below the removable cover, such that a gap is formed between the removable cover and the absorbing material.

9. The method of claim 8, further comprising applying an alert module to the housing base to communicate a notification when the absorbing material expands in a presence of a liquid.

10. The method of claim 9, wherein the conductive material contacts the conductive surface and forms a closed circuit when the absorbing material expands.

11. The method of claim 8, further comprising forming a pair of conductive extensions coupled to the conductive material such that the pair of extensions extend from the conductive material and form a cavity over a surround base encompassing the absorbing material having the conductive material.

12. The method of claim I 1, wherein the pair of conductive extensions form an open circuit when detached from the surround base upon the absorbing material expanding in a presence of a liquid.

13. The method of claim 12, further comprising interchangeably coupling the surround base in a location of the recess of the housing base.

14. A system comprising:
a control module; and
a plurality of sensors configured to automatically communicate with the control module, each of the plurality of sensors to include an absorbing material capable of expansion on contact with a liquid, and a conductive material adjacent to the absorbing material to form at least one of an open circuit and a closed circuit when the absorbing material expands.

15. The system of claim 14, wherein at least one of the plurality of sensors to include an alert module to wirelessly communicate with the control module when the absorbing material expands beyond a threshold value.

16. The system of claim 14, wherein the control module is shared across the plurality of sensors and other devices in a structure.

17. The system of claim 14, wherein the control module to automatically choke a liquid source location when the absorbing material expands.

18. The system of claim 14, wherein at least some of the plurality of sensors are each physically less than two inches by two inches in a length, in a width, and in a height, such the at least some of the plurality of sensors can be integrated inside a structural wall.

19. The system of claim 14, further comprising a data processing system coupled to the control module through a network to remotely detect a presence of a liquid in an enclosed structure when the absorbing material expands.

20. The system of claim 14, wherein the control module to automatically communicate through a network to a location external to the enclosed structure when the absorbing material in at least one of the plurality of sensors expands.
